(19) United States
(12) Patent Application Publication
(10) Pub. No.: US 2002/0110765 A1
(43) Pub. Date: Aug. 15, 2002

(54) Photolithography process for producing gates and conductive lines

(75) Inventors: Chien-Wen Lai, Taipei Hsien (TW); Chien-Ming Wang, Hsinchu Hsien (TW); Chuen-Huei Yang, Taipei (TW); Andersen Chang, Miaoli Hsien (TW)

Correspondence Address: J. C. PATENTS, 4 VENTURE , SUITE 250, IRVINE, CA, 92618, US

(73) Assignee: United Microelectronics Corp., Hsinchu (TW)

(21) Appl. No.: 09/780,784

(22) Filed: Feb. 9, 2001

(51) Int. Cl. G03F 7/20

(52) U.S. Cl. 430/394; 430/313; 430/396

(57) ABSTRACT

A lithography process for producing gates and connections thereof, which can reduce the pitch of gate end connections is provided. The process comprises the steps of forming a photoresist layer on the substrate; exposing the photoresist layer by using a phase shifter mask to form a gates pattern in the photoresist layer in the device region; exposing the photoresist layer by using a trimming mask to form a conductive lines pattern connected to the gates pattern in the photoresist layer in the isolation region; and developing the photoresist layer. The trimming mask can be a half-tone mask or a Cr-less alternating phase shifter

### BACKGROUND OF THE INVENTION

1. Field of the Invention

The present invention relates to a semiconductor process, especially a lithography process for producing gates and connections thereof

2. Description of the Related Art

A gate is used to control opening/closing of a channel in a MOS transistor. The gate is located on the device region of the substrate. A connection at the end of the gate is located on an isolation region of the substrate. In various electronic products, the device region has a plurality of gates in parallel. The linewidth for the gate is the critical dimension (CD) for the semiconductor process. The connection at the end of the gate has various shapes. The linewidth of the connection can be slightly greater than that of the gate. With increasing integration of the semiconductor device, the linewidth of the gate becomes smaller and smaller, even smaller than the wavelength of an exposure source. Therefore, special methods are used to reduce and control the pitch/size.

Usually, two different masks are used to perform a double exposure to form the gates pattern and the gate end connections pattern in photoresist layers in the device region and the isolation region, respectively, in a conventional photolithography process. Since the gates pattern is arranged in parallel, an alternating phase shifter mask is required to form the gates pattern. Adjacent transparent regions have opposite phases in this type of mask, resulting in better exposure contrast and reduced pitch for patterns. On the other hand, since the gate end connections have various shapes, the alternating phase shifter mask can be not used. Therefore, a common chromium (Cr) metal mask having only opaque Cr metal patterns thereon is used to form gate end connections pattern in the art. For example, referring to FIG.1, which shows a gate end connections pattern of a mask 10 which has a T-shape portion 12, both a non phase shifting (0 degree) layer and/or a 180 degree phase shifting layer can be used in the vertical section of the T-shape portion 12 to adjust the region to be exposed and thus obtain the desired pattern. However, in this case, neither the non phase shifting (0 degree) layer nor the 180 degree phase shifting layer can work in the horizontal section of the T-shape portion 12.

As is well known to those in the art, a common Cr metal mask has a lower resolution than an alternating phase shifter mask, such that a smaller pitch cannot be obtained. That is, when the design rule for the device requires a smaller pitch, an alternating phase shifter mask is used to form gates having a smaller pitch. The pitch for the gate end connections is limited to the features of the Cr metal mask, such that it is not easy to reduce the pitch. Therefore, it is not easy to make the size of the whole chip smaller, as the area occupied by the gates can not be reduced.

### SUMMARY OF THE INVENTION

Therefore, the present invention provides a lithography process for producing gates and connections thereof, which can reduce the pitch of gate end connections, the process comprising the steps of forming a photoresist layer on the substrate; exposing the photoresist layer by using a phase shifter mask, such as an alternating phase shifer mask, to form a gates pattern in the photoresist layer in the device region; and exposing the photoresist layer by using a trimming mask to form a conductive lines pattern connected to the gates pattern in the photoresist layer in the isolation region. The trimming mask can be a half-tone mask or a Cr-less alternating phase shifter mask. Finally, the photoresist layer is developed.

As mentioned above, a half-tone mask or a Cr-less alternating phase shifter mask is used to form the gate end connections pattern in the present invention. These two masks have improved resolutions over a conventional chromium metal mask and are comparable with the alternating phase shifter mask. Therefore, the pitch of the gate end connections pattern can be as small as that of the gates pattern, resulting in reduced areas of the patterns and thus a reduced die size.

### BRIEF DESCRIPTION OF THE DRAWINGS

It is to be understood that both the foregoing general description and the following detailed description are exemplary, and are intended to provide further explanation of the invention as claimed.

The accompanying drawings are included to provide a further understanding of the invention, and are incorporated in and constitute a part of this specification. The drawings illustrate embodiments of the invention and, together with the description, serve to explain the principle of the invention. In the drawings,

FIG. 1 diagrammatically illustrates why the gate end connections pattern can not be defined by using an alternating phase shifter mask;

FIGS. 2 and 3 illustrate a lithography process for producing gates and conductive lines according to one preferred embodiment of the present invention;

FIG. 2A shows an alternating phase shifter mask used in the above lithography process for defining gates; and

FIGS. 3A and 3B illustrate a trimming mask, which is a half-tone mask or Cr-less alternating phase shifter mask, used for defining conductive lines.

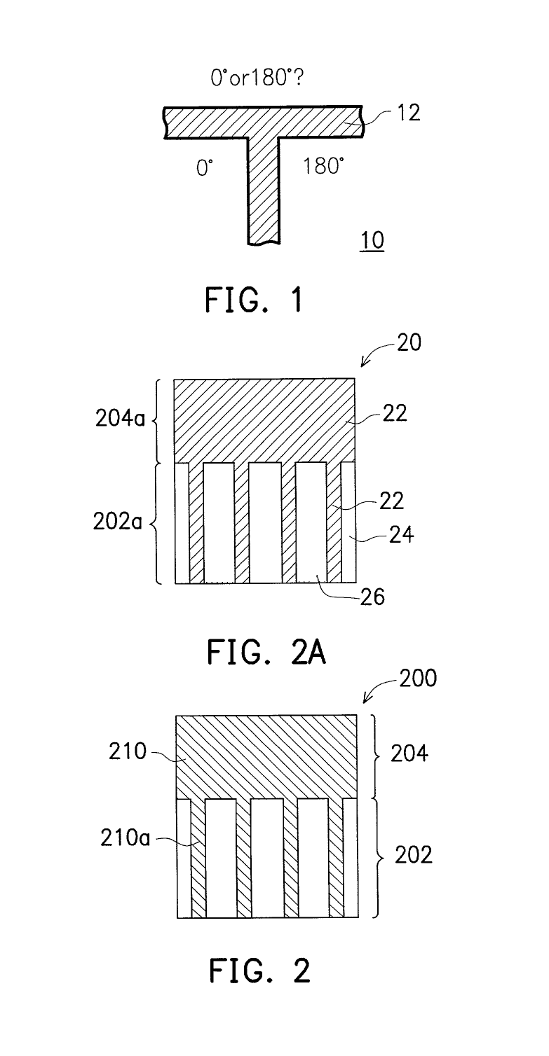

### DESCRIPTION OF THE PREFERRED EMBODIMENT

Reference will now be made in detail to the present preferred embodiments of the invention, examples of which are illustrated in the accompanying drawings. Whenever possible, the same reference numbers are used in the drawings and the description to refer to the same or like parts.

FIG. 2A shows a mask used for defining gates in a photolithography process according to one preferred embodiment of the present invention. Referring to FIG. 2A, an alternating phase shifter mask 20 has an opaque region 22, a transparent region 24 and a transparent phase shifting region 26. The alternating phase shifter mask 20 is divided into a device mask region 202a and an isolation mask region 204a. The opaque region 22 covers the whole isolation mask region 204a. The pattern of the opaque region 22 in the device mask region 202a is used to form a plurality of gates pattern in parallel. The transparent region 24 and the transparent phase shifting region 26 are separated by the opaque region 22, periodically. The transparent phase shifting region 26 has a phase shifting angle of 180 degree and a transmittance of 100%.

FIG. 2 shows defining gates and conductive lines in a photolithography according to one preferred embodiment of the present invention. First, a substrate 200 having a device region 202 and an isolation region 204 is provided. A conductive layer (not shown) is formed on the substrate for formation of the gates and the conductive lines. Subsequently, a positive mask layer 210 is formed on the conductive layer, and exposed by using the above alternating phase shifter mask 20 to form the gates pattern 210a in the positive mask layer 210 in the device region 202. Because the wave amplitude in the region between the transparent region 24 and the transparent phase shifting region 26 of the alternating phase shifter mask 20 (FIG. 2A) would be offset, the gates pattern 210a gets an improved exposure contrast, resulting in a reduced pitch. Further, since the mask region for isolation 204a of the alternating phase shifter mask 20 is a part of the opaque region 22, the positive mask layer 210 of the isolation region 204 would not be affected.

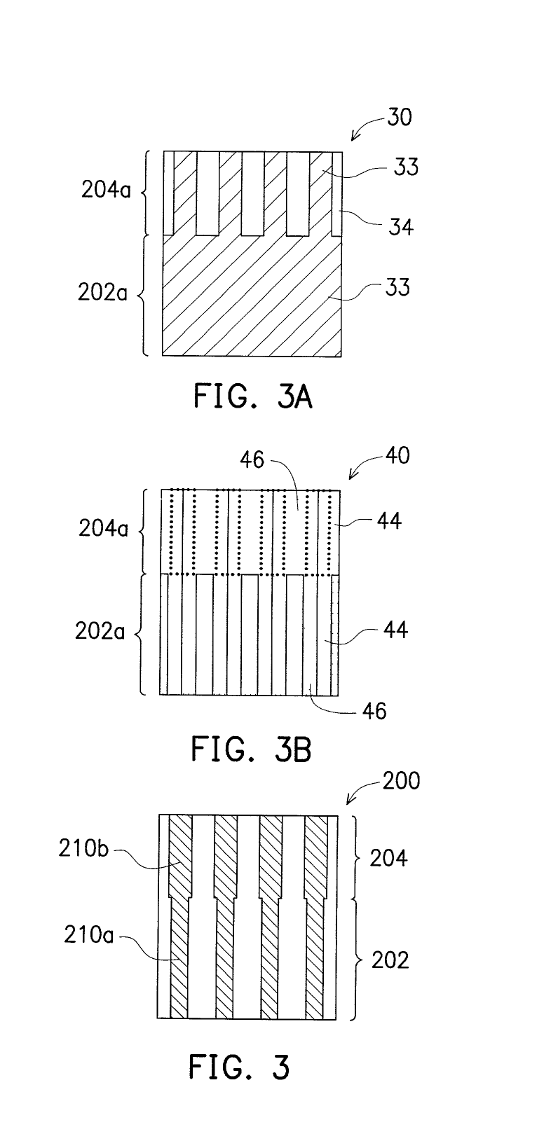

FIG. 3A shows a trimming mask used for defining conductive lines according to one preferred embodiment of the present invention. Referring to FIG. 3A, a half-tone mask 30 has a low transmittance phase shifting region 33 and a transparent region 34. The half-tone mask 30 is divided into a device mask region 202a and an isolation mask region 204a. The pattern of the low transmittance phase shifting region 33 in the isolation mask region 204a is used to form a conductive lines pattern connected to the gates pattern 210a (FIG. 2A). The low transmittance phase shifting region 33 covers the device mask region 202a completely. The low transmittance phase shifting region 33 has a phase shifting angle of 180 degree and a transmittance of more than 6%, for example.

FIG. 3 shows defining conductive lines according to one preferred embodiment of the present invention. As shown in FIG. 3, the positive mask layer 210 is exposed by using the above half-tone mask 30 to form a conductive lines pattern 210b connected to the gates pattern 210a in the positive mask layer 210 in the isolation region 204 (FIG. 2). Since the low transmittance phase shifting region 33 in the isolation mask region 204a of the half-tone mask 30 can be used to offset the wave amplitude outside the boundary of the transparent region 34 (FIG. 3A), the conductive lines pattern 210b gets an improved exposure contrast, resulting in a reduced pitch. Further, because the device mask region 202a of the half-tone mask 30 is a part of the low transmittance phase shifting region 33, the gates pattern 210a of the device region 202 would not be affected.

FIG. 3B shows another trimming mask used for defining a conductive lines pattern according to one preferred embodiment of the present invention. As shown in FIG. 3B, a Cr-less alternating phase shifter mask 40 has a transparent region 44 and a transparent phase shifter region 46. The Cr-less alternating phase shifter mask 40 is divided into a device mask region 202a and an isolation mask region 204a. The transparent phase shifting region 46 has a phase shifting angle of 180 degree and a transmittance of 100%. The pitch of the transparent phase shifting region 46/tranparent region 44 in the mask region for device 202a is small enough to shield the device mask region 202a from light transmitting and thus prevent the gates pattern 210a of the device region 202 from being affected. The pitch/size of the transparent phase shifting region 46/transparent region 44 in the isolation mask region 204a is larger, resulting in insufficient exposure only near the boundary between transparent phase shifting region 46 and the transparent region 44, indicated by dotted lines in FIG. 3B. The conductive lines pattern 210b as shown in FIG. 3 is thus formed in the positive mask layer 210 (FIG. 2).

It should be understood that although the positive mask is exemplified in the above embodiments, a negative photoresist layer which has an exposure region complementary to the positive mask can be used in the present invention, For a half-tone mask matching the negative photoresist (not shown), a low transmittance phase shifting region/transparent region complementary to the low transmittance phase shifting region 33/transparent region 34 in the isolation mask region 204a of FIG. 3A could be used in order to form the conductive lines pattern as shown in FIG. 3. For a Cr-less alternating phase shifter mask (not shown), a central portion of a transparent phase shifting region and a central portion of a transparent region are required to be located at the boundary between the transparent phase shifting region 46 and the transparent region 44 in the isolation mask region 204a shown in FIG. 3B, such that the low exposure region, in the case of positive photoresist, becomes a high exposure region in this case. Thereby, the conductive lines pattern as shown in FIG. 3 is obtained.

As mentioned above, the half-tone mask 30(FIG. 3A) or the Cr-less alternating phase shifter mask 40 (FIG. 3B) used in the preferred embodiments of the present invention has improved resolution over a conventional chromium metal mask and is comparable with the alternating phase shifter mask. Therefore, the pitch of the conductive lines pattern connected to the gates pattern, obtained in subsequent etching process, can be as small as that of the gates pattern. Therefore, reduced areas thereof and thus a reduced die size can be obtained.

Furthermore, the process of the present invention can also be used with other photolithography, provided that the photolithography process forms a first pattern in a parallel way in a first region, and forms a second pattern with a non orderly spaced arrangement in a second region. An alternating phase shifter mask is used to form the first pattern so as to reduce the pitch for the first pattern. A half-tone mask or a Cr-less alternating phase shifter mask is used to form the second pattern so as to reduce the pitch for the second pattern.

It will be apparent to those skilled in the art that various modifications and variations can be made to the structure of the present invention without departing from the scope or spirit of the invention. In view of the forgoing, it is intended that the present invention cover modification and variation of this invention provided they fall within the scope of the following claims and their equivalents.

What is claimed is:

1. A photolithography process for producing gates and conductive lines, suitable for a substrate having a device region and an isolation region, the process comprising:
forming a photoresist layer on the substrate;
exposing the photoresist layer by using a phase shifter mask to form a plurality of gates pattern in the photoresist layer in the device region;
exposing the photoresist layer by using a half-tone mask to form a plurality of conductive lines pattern connected to the gates pattern in the photoresist layer in the isolation region, the conductive lines pattern on the half-tone mask consisting of a plurality of low transmittance phase shifting regions and a plurality of transparent regions; and
developing the photoresist layer.

2. The photolithography process of claim 1, wherein the low transmittance phase shifting region has a phase shifting angle of 180 degree.

3. The photolithography process of claim 1, wherein the low transmittance phase shifting region has transmittance of more than 6%.

4. The photolithography process of claim 1, wherein the low transmittance phase shifting region of the half-tone mask is used to shield the device region, and wherein the low transmittance region is made of the same material as the low transmittance phase shifting region.

5. The photolithography process of claim 1, wherein the phase shifter mask is a alternating phase shifter mask.

6. The photolithography process of claim 1, wherein the photoresist layer is a positive photoresist layer.

7. The photolithography process of claim 1, wherein the photoresist layer is a negative photoresist layer.

8. A photolithography process for producing gates and conductive lines, suitable for a substrate having a device region and an isolation region, the process comprising:
forming a photoresist layer on the substrate;
exposing the photoresist layer by using a phase shifter mask to form a plurality of gates pattern in the photoresist layer in the device region;
exposing the photoresist layer by using a Cr-less alternating phase shifter mask to form a plurality of conductive lines pattern connected to the gates pattern in the photoresist layer in the isolation region, the conductive lines pattern on the Cr-less alternating phase shifting mask consisting of a plurality of first transparent phase shifting regions and a plurality of first transparent regions in sequence; and
developing the photoresist layer.

9. The photolithography process of claim 8, wherein the first transparent phase shifting region has transmittance of 100%.

10. The photolithography process of claim 8, wherein the Cr-less alternating phase shifting mask has a low transmittance region to shield the device region, the low transmittance region consisting of a plurality of second transparent phase shifting regions and a plurality of second transparent regions in sequence, and wherein the second transparent phase shifting regions are made of the same material as the first transparent phase shifting regions.

11. The photolithography process of claim 8, wherein the phase shifter mask is a alternating phase shifter mask.

12. The photolithography process of claim 8, wherein the photoresist layer is a positive photoresist layer.

13. The photolithography process of claim 8, wherein the photoresist layer is a negative photoresist layer.

14. A photolithography process suitable for a substrate having a first region and a second region, the process comprising:
forming a photoresist layer on the substrate;
exposing the photoresist layer by using an alternating phase shifter mask to form a plurality of first pattern arranged in parallel in the photoresist layer in the first region;
exposing the photoresist layer by using a trimming mask to form a plurality of second pattern with non orderly spaced arrangements in the photoresist layer in the second region, the trimming mask being one of a half-tone mask and a Cr-less alternating phase shifter mask and having a low transmittance region used to shield the first region; and
developing the photoresist layer, wherein
when the trimming mask is a half-tone mask, the second patterns on the trimming mask consists of a plurality of low transmittance phase shifting regions and a plurality of transparent regions; and
when the trimming mask is a Cr-less alternating phase shifter mask, the second patterns on the trimming mask consists of a plurality of first transparent phase shifting regions and a plurality of first transparent regions

15. The photolithography process of claim 14, wherein the trimming mask is a half-tone mask and the low transmittance phase shifting region has transmittance of more than 6%.

16. The photolithography process of claim 14, wherein the trimming mask is a half-tone mask and the low transmittance phase shifting region has the phase shifting angle of 180 degree.

17. The photolithography process of claim 14, wherein the trimming mask is a half-tone mask and the low transmittance region is made of the same material as the low transmittance phase shifting region.

18. The photolithography process of claim 14, wherein the trimming mask is a Cr-less alternating phase shifter mask and the first transparent phase shifting region has transmittance of 100%.

19. The photolithography process of claim 14, wherein the trimming mask is a Cr-less alternating phase shifter mask, the low transmittance region consisting of a plurality of second transparent phase shifting regions and a plurality of second transparent regions in sequence, and wherein the second transparent phase shifting regions are made of the same material as the first transparent phase shifting regions.

20. The photolithography process of claim 14, wherein the photoresist layer is a positive photoresist layer or a negative photoresist layer.
